(19) United States
(12) Patent Application Publication
(10) Pub. No.: US 2009/0267221 A1
(43) Pub. Date: Oct. 29, 2009

(54) SEMICONDUCTOR DEVICE

(75) Inventor: Tomoharu FUJII, Nagano-shi (JP)

Correspondence Address: DRINKER BIDDLE & REATH (DC), 1500 K STREET, N.W., SUITE 1100, WASHINGTON, DC, 20005-1209, US

(73) Assignee: SHINKO ELECTRIC INDUSTRIES CO., LTD., Nagano-shi (JP)

(21) Appl. No.: 12/428,594

(22) Filed: Apr. 23, 2009

(30) Foreign Application Priority Data
Apr. 24, 2008 (JP) 2008-113333

(51) Int. Cl. H01L 23/538

(52) U.S. Cl. 257/698; 257/E23.174

(57) ABSTRACT

An antenna formed on one surface side of a silicon substrate and a semiconductor element provided on the other surface side of the silicon substrate are electrically connected to each other by means of a through via penetrating the silicon substrate. A wiring board is formed separately from the silicon substrate. A passive element is provided on one surface side of the wiring board. A copper core solder ball is provided between the one surface side of the wiring board and the other surface side of the silicon substrate and electrically connects the silicon substrate and the wiring board to each other.

This application claims priority to Japanese Patent Application No. 2008-113333, filed Apr. 24, 2008, in the Japanese Patent Office. The Japanese Patent Application No. 2008-113333 is incorporated by reference in its entirety.

### TECHNICAL FIELD

The present disclosure relates to a semiconductor device, and more particularly to a semiconductor device which has an antenna formed therein and is used for a radio communication.

### RELATED ART

As a semiconductor device provided with an antenna to be used for a radio communication, a semiconductor device shown in FIG. 5 has been proposed in the following Patent Document 1. In the semiconductor device shown in FIG. 5, a semiconductor element 102 to be an active element and a chip capacitor 104 to be a passive element which are provided on one surface side of a wiring board 100 are sealed with a sealing resin layer 106. An antenna 108 is formed on a surface of the sealing resin layer 106. The antenna 108 is electrically connected to the wiring board 100 through terminals 110 and 110.

The antenna 108 is covered with a protective film 112 and external connecting terminals 114 and 114 are formed on the other surface side of the wiring board 100.

[Patent Document 1] JP-A-2007-42978 Publication

The semiconductor device shown in FIG. 5 can be reduced in a size and can be used in a radio module such as a portable telephone.

In the semiconductor device shown in FIG. 5, a heat is radiated from the semiconductor element 102 to be the active element provided on the one surface side of the wiring board 100 through the wiring board 100 or the sealing resin layer 106.

For this reason, in case of a semiconductor device provided with the radio frequency semiconductor element 102, there is a possibility that the radiation of the heat from the semiconductor element 102 might be insufficient. Therefore, it has been desirable to enhance the heat radiating property of the semiconductor device shown in FIG. 5.

### SUMMARY

Exemplary embodiments of the present invention provide a semiconductor device provided with an antenna which can rapidly radiate a heat from a semiconductor element provided thereon.

The inventor tried a semiconductor device shown in FIG. 6. In the semiconductor device shown in FIG. 6, an antenna 202, a semiconductor element 204, and a chip capacitor 206 and a quartz oscillator 208 to be a passive element are provided on one surface side of a wiring board 200, and the semiconductor element 204, the chip capacitor 206 and the quartz oscillator 208 are sealed with a sealing resin layer 210.

In order to rapidly radiate a heat of the semiconductor element 204 which is provided, furthermore, a plurality of heat radiating vias 212 and 212 penetrating the wiring board 200 is formed.

When the semiconductor device shown in FIG. 6 is mounted on a mother board, the heat of the semiconductor element 204 can be rapidly radiated to the mother board through the heat radiating vias 212 and 212.

However, the antenna 202 is formed on the one surface side of the wiring board 200 so that a size of the wiring board 200 is increased. Furthermore, the heat radiating vias 212 and 212 are formed on the wiring board 200 so that a degree of freedom of a design in the wiring board 200 is limited.

For this reason, the inventor supposed that a semiconductor element is provided on a silicon substrate, which has a higher thermal conductivity as compared with a wiring board formed by a resin or ceramic and is capable of forming a conductor pattern, and a passive element such as a chip capacitor is provided on a wiring board, and a heat of the semiconductor element can be thus radiated rapidly, and repetitively made further investigations, resulting in the invention.

More specifically, the invention provides a semiconductor device comprising;

a silicon substrate;

an antenna formed on one surface side of the silicon substrate;

a semiconductor element to be an active element which is provided on the other surface side of the silicon substrate;

a through via penetrating the silicon substrate and electrically connecting the antenna and the semiconductor element to each other;

a wiring board formed separately from the silicon substrate;

a passive element provided on one surface side of the wiring board; and a connecting member provided between the one surface side of the wiring board and the other surface side of the silicon substrate and electrically connecting the silicon substrate and the wiring board to each other.

In the invention, by providing an insulating layer formed of SiO₂ or SiN on an outer peripheral surface including an inner peripheral surface of a through hole of the silicon substrate, it is possible to easily form a wiring pattern on a surface of the silicon substrate.

By using, as the connecting member, a solder ball in which a solder layer is formed on an outer peripheral surface of a core portion, it is possible to reliably cause an interval between the silicon substrate and the wiring board to have a predetermined width.

By sealing a portion between the silicon substrate and the wiring board with a sealing resin, it is possible to reliably seal the semiconductor element and the passive element.

By attaching an external connecting terminal to the other surface side of the wiring board, furthermore, it is possible to easily mount the semiconductor device on a mother board.

By using, as the wiring board, a wiring board formed by a resin, it is possible to reduce a weight of the semiconductor device.

In the semiconductor device according to the invention, the semiconductor element to be the active element is provided on the other surface side of the silicon substrate having the antenna formed on the one surface side which is opposed to the one surface side of the wiring board on which the passive element such as a chip capacitor is provided.

Silicon for forming the silicon substrate has a thermal conductivity of 168 W·m⁻¹·K⁻¹. On the other hand, an epoxy resin to be a material for forming the wiring board has a thermal conductivity of 0.03 W·m⁻¹·K⁻¹ and alumina ceramic has a thermal conductivity of 30.2 W·m⁻¹·K⁻¹. Thus, the silicon substrate formed of the silicon is more excellent in a heat radiating property than a wiring board formed by a resin or ceramic.

In the semiconductor device according to the invention, therefore, a heat of the semiconductor element can be directly radiated from the silicon substrate rapidly. As a result, it is possible to provide a radio frequency semiconductor element.

In the semiconductor device according to the invention, moreover, the semiconductor element is not provided on the wiring board but only the passive element such as a chip capacitor is provided and a heat radiating via does not need to be formed. Consequently, it is possible to enhance a degree of freedom of a design in the wiring board.

Other features and advantages may be apparent from the following detailed description, the accompanying drawings and the claims.

### BRIEF DESCRIPTION OF THE DRAWINGS

FIG. 1 is a longitudinal sectional view for explaining an example of a semiconductor device according to the invention,

FIGS. 2A to 2F are views for explaining a step of manufacturing a silicon substrate 18 constituting the semiconductor device illustrated in FIG. 1,

FIGS. 3A and 3B are views for explaining a part of a step of manufacturing a wiring board 10 constituting the semiconductor device illustrated in FIG. 1,

FIG. 4 is a view for explaining a step of integrating the silicon substrate 18 obtained at the manufacturing step illustrated in FIG. 2 with the wiring board 10 obtained at the manufacturing step illustrated in FIG. 3,

FIG. 5 is a longitudinal sectional view for explaining a related-art semiconductor device provided with an antenna, and

FIG. 6 is a longitudinal sectional view showing a semiconductor device obtained by improving the related-art semiconductor device.

### DETAILED DESCRIPTION

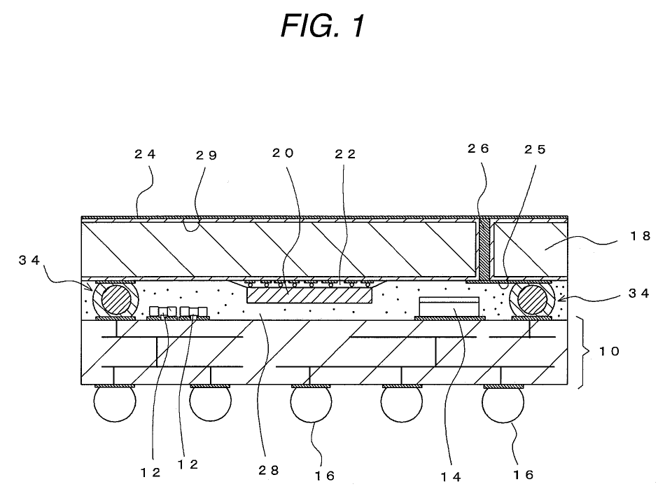

FIG. 1 shows an example of a semiconductor device according to the invention. In the semiconductor device shown in FIG. 1, passive elements such as chip capacitors 12 and 12 and a quartz oscillator 14 are provided on one surface side of a multilayer wiring board 10 formed by a resin (which will be hereinafter referred to as a wiring board 10). Solder balls 16 and 16 to be external connecting terminals are attached to the other surface side of the wiring board 10.

A silicon substrate 18 is provided opposite to the one surface side of the wiring board 10. The silicon substrate 18 has a thickness of 200 to 300 μm and is formed of silicon having a higher thermal conductivity than the resin forming the wiring board 10, and has a surface layer on which an insulating layer 29 formed of SiO₂ is provided.

The silicon substrate 18 has an antenna 24 formed on one surface side thereof and has a semiconductor element 20 provided on the other surface side. A portion between an electrode side of the semiconductor element 20 and the other surface side of the silicon substrate 18 is sealed with an underfilling agent 22.

Furthermore, the antenna 24 formed on the one surface side of the silicon substrate 18 is electrically connected to a conductor pattern 25 formed on the other surface side of the silicon substrate 18 by means of a through via 26 penetrating the silicon substrate 18. The insulating layer 29 formed of the SiO₂ is provided on an internal wall surface of a through hole in which the through via 26 is formed. The conductor pattern 25 is also connected electrically to the semiconductor element 20 provided on the silicon substrate 18.

For the antenna 24, it is possible to form an antenna taking an optional shape which is adapted to a purpose of use. For example, it is possible to form an antenna taking an inverse L shape or an inverse F shape.

The one surface side of the wiring board 10 on which the chip capacitors 12 and 12 are provided and the other surface side of the silicon substrate 18 on which the semiconductor element 20 is provided are electrically connected to each other through copper core solder balls 34 and 34 to be connecting members in a state in which they are disposed opposite to each other. The copper core solder ball 34 is a solder ball in which a solder layer is formed on an outer peripheral surface of a core portion made of copper.

A predetermined gap is formed through the copper core solder balls 34 and 34 between the wiring board 10 and the silicon substrate 18. The passive elements such as the chip capacitors 12 and 12 and the semiconductor element 20 which are provided in the gap are sealed with a sealing resin 28.

Thus, the wiring board 10 and the silicon substrate 18 are electrically connected to each other through the copper core solder balls 34 and 34. Therefore, the passive elements such as the chip capacitors 12 and 12 provided on the one surface side of the wiring board 10, and the semiconductor device 20 provided on the other surface side of the silicon substrate 18 and the antenna 24 formed on the one surface side of the silicon substrate 18 are electrically connected to each other.

According to the semiconductor device shown in FIG. 1, the heat is directly radiated from the semiconductor element 20 through the silicon substrate 18. Even if a radio frequency semiconductor element having a high calorific power is provided as the semiconductor element 20, therefore, an amount of heat radiation can be sufficiently maintained.

Furthermore, a whole surface on the one surface side of the silicon substrate 18 can be used as a surface on which the antenna 24 is to be formed. Consequently, it is possible to enhance a degree of freedom of a design in the antenna 24. In addition, for the silicon substrate 18, it is sufficient that an area of a radiator plate of the semiconductor element 20 is ensured. Thus, it is possible to reduce a size of the semiconductor device.

For the wiring board 10 provided with the chip capacitor 12, moreover, it is not necessary to take the heat radiating property of the semiconductor element 20 into consideration. Thus, it is also possible to enhance the degree of freedom of a design in the wiring board 10.

The semiconductor device shown in FIG. 1 can be suitably used for a radio module such as a portable telephone.

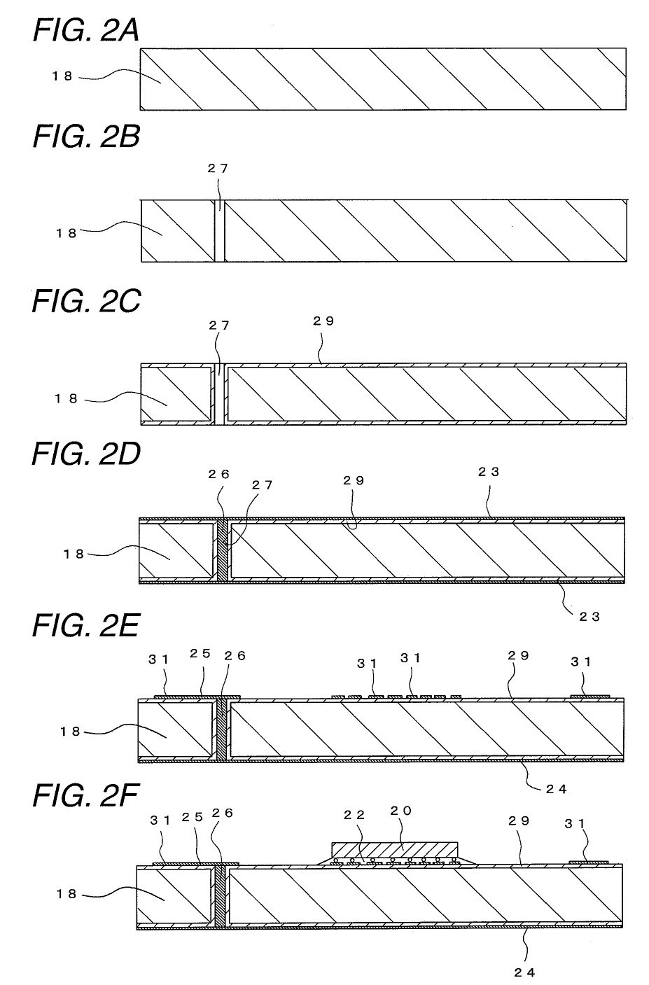

In order to manufacture the semiconductor device shown in FIG. 1, first of all, a through hole 27 for forming a through via is provided on a silicon substrate 18 having a thickness of 200 to 300 μm as shown in FIGS. 2A and 2B. The through hole 27 may be formed by a laser or etching.

Furthermore, an insulating layer 29 formed of SiO₂ is provided on a surface layer of the silicon substrate 18 including an internal wall surface of the through hole 27 (FIG. 2C). The insulating layer 29 can be formed by heat treating the silicon substrate 18 in an oxygen atmosphere.

Subsequently, the through hole 27 formed on the silicon substrate 18 is filled with copper to form a through via 26 and copper layers 23 and 23 on both surface sides of the insulating layer 29 as shown in FIG. 2D.

The through via 26 and the copper layers 23 and 23 are formed in the following manner. A thin copper film is formed on a whole surface of the insulating layer 29 of the silicon substrate 18 by electroless copper plating or sputtering and the copper is then filled in the through hole 27 by electrolytic copper plating using the thin copper film as a feeding layer, and the copper layers 23 and 23 are formed on the both surface sides of the silicon substrate 18.

Furthermore, patterning is carried out over one of the copper layers 23 and 23 formed on the both surface sides of the silicon substrate 18 to form an antenna 24, and the patterning is carried out over the copper layer 23 on the other surface side to form a conductor pattern 25 and pads 31 and 31 (FIG. 2E). For the antenna 24, it is possible to form an antenna taking an optional shape which is adapted to a purpose of use. For example, it is possible to form an inverse L-shaped antenna or an inverse F-shaped antenna.

As shown in FIG. 2F, then, a semiconductor element 20 is provided on the predetermined pads 31 and 31 in a predetermined place on the other surface side of the silicon substrate 18 through a flip chip method and a portion between an electrode side of the semiconductor element 20 and the other surface side of the silicon substrate 18 is thereafter sealed with an underfilling agent 22.

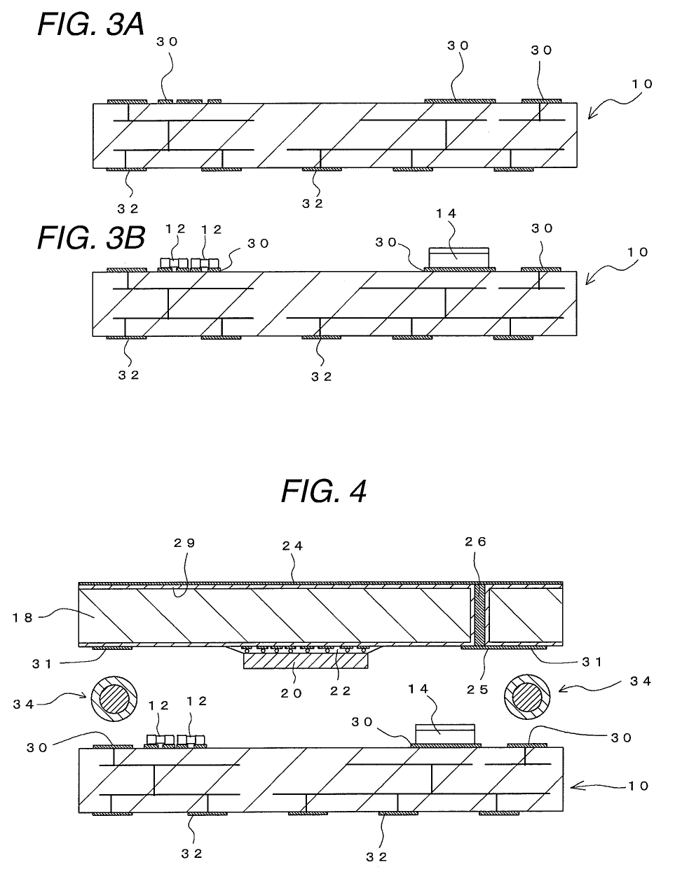

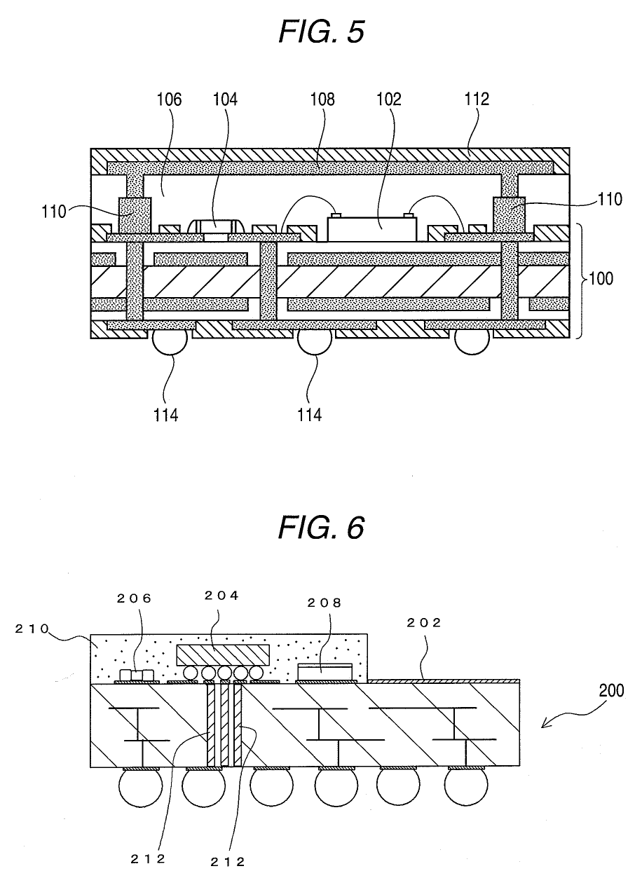

As illustrated in FIG. 3, a passive element such as a chip capacitor is provided on a wiring board 10 to be used together with the silicon substrate manufactured in the manufacturing process shown in FIG. 2.

As shown in FIG. 3A, first of all, the multilayer wiring board 10 is formed. The wiring board 10 may be a wiring board formed by a resin through a buildup method or may be a wiring board formed of ceramic by laminating, with an adhesive, a plurality of ceramic boards having a predetermined wiring pattern provided on both surface sides.

Pads 30 and 30 on which the chip capacitor is to be provided are formed on one surface side of the wiring board 10, and a pad 32 to which a solder ball 16 to be an external connecting terminal is formed on the other surface side thereof.

As shown in FIG. 3B, chip capacitors 12 and 12 and a quartz oscillator 14 are provided on the pads 30 and 30 formed on one surface side of the wiring board 10.

Referring to the silicon substrate 18 shown in FIG. 2F and the wiring board 10 shown in FIG. 3B, the one surface side of the silicon substrate 18 on which the semiconductor element 20 is provided is electrically connected to the other surface side of the wiring board 10 on which the passive elements such as the chip capacitors 12 and 12 are provided through copper core solder balls 34 and 34 to be connecting members as shown in FIG. 4. The copper core solder balls 34 and 34 are positioned and provided between the pad 30 of the wiring board 10 and the pad 31 of the silicon substrate 18 and are then subjected to a reflow so that both of them can be electrically connected to each other.

By using the copper core solder balls 34 and 34 as the connecting members, thus, it is possible to reliably form a clearance having a predetermined interval between the silicon substrate 18 and the wiring board 10.

Subsequently, a portion between the silicon substrate 18 and the wiring board 10 is sealed with a mold resin, and the solder balls to be the external connecting terminals are then provided on each of the pads 32 and 32 of the wiring board 10 to carry out a reflow. Consequently, it is possible to obtain the semiconductor device shown in FIG. 1.

Although the copper core solder balls 34 and 34 are used as the connecting members in FIGS. 1 and 4, it is also possible to utilize a resin core solder ball using a resin material as a core material for the core portion.

Although the insulating layer 29 formed of the SiO₂ is formed on the surface layer including the internal wall surface of the through hole 27 in the silicon substrate 18, moreover, the insulating layer 29 formed of SiN may be formed. The insulating layer 29 constituted by the SiN can be formed by heat treating the silicon substrate 18 provided with the through hole 27 in a nitrogen atmosphere.

While the invention has been described with respect to a limited number of embodiments, those skilled in the art, having benefit of this disclosure, will appreciate that other embodiments can be devised which do not depart from the scope of the invention as disclosed herein. Accordingly, the scope of the invention should be limited only by the attached claims.

What is claimed is:

1. A semiconductor device comprising;
a silicon substrate;
an antenna formed on one surface side of the silicon substrate;
a semiconductor element to be an active element which is provided on the other surface side of the silicon substrate;
a through via penetrating the silicon substrate and electrically connecting the antenna and the semiconductor element to each other;
a wiring board formed separately from the silicon substrate;
a passive element provided on one surface side of the wiring board; and
a connecting member provided between the one surface side of the wiring board and the other surface side of the silicon substrate and electrically connecting the silicon substrate and the wiring board to each other.

2. The semiconductor device according to claim 1, further comprising:
an insulating layer formed of SiO₂ or SiN and provided on an outer peripheral surface including an inner peripheral surface of a through hole in the silicon substrate.

3. The semiconductor device according to claim 1, wherein the connecting member is a solder ball in which a solder layer is formed on an outer peripheral surface of a core portion.

4. The semiconductor device according to claim 1, wherein the wiring board is formed by a resin.

5. The semiconductor device according to claim 1, further comprising:
a sealing resin sealing a portion between the one surface side of the wiring board and the other surface side of the silicon substrate.

6. The semiconductor device according to claim 1, wherein an external connecting terminal is attached to the other surface side of the wiring board.
